(19) United States
(12) Patent Application Publication
(10) Pub. No.: US 2025/0247120 A1
(43) Pub. Date: Jul. 31, 2025

(54) RECEIVER CIRCUIT AND A METHOD OF OPERATING THE SAME

(71) Applicant: SAMSUNG ELECTRONICS CO., LTD., Suwon-si (KR)

(72) Inventors: WONHO JANG, Suwon-si (KR); Gichul Jung, Suwon-si (KR); Kyungho Ryu, Suwon-si (KR); Jung-Pil Lim, Suwon-si (KR); Eun-Young Jin, Suwon-si (KR); Mangi Han, Suwon-si (KR); Junho Han, Suwon-si (KR)

(73) Assignee: SAMSUNG ELECTRONICS CO., LTD., Suwon-si (KR)

(21) Appl. No.: 18/978,857

(22) Filed: Dec. 12, 2024

(30) Foreign Application Priority Data
Jan. 26, 2024 (KR) 10-2024-0012375

(51) Int. Cl. H04B 1/16; H04B 17/21

(52) U.S. Cl. CPC H04B 1/1607; H04B 17/21

(57) ABSTRACT

A receiver circuit and a method of operating the receiver circuit are provided. The receiver circuit includes: a first stage circuit configured to perform a waveform adjustment or amplification operation on first and second input differential signals; a replica circuit configured to receive a common mode voltage and perform a waveform adjustment operation or amplification operation on the common mode voltage; a multiplexer that is configured to output one of an output of the first stage circuit and an output of the replica circuit as first and second intermediate differential signals based on an offset calibration enable signal; and an offset calibration logic configured to receive a digital signal generated based on the first and second intermediate differential signals, and perform an offset calibration operation based on the digital signal.

### CROSS-REFERENCE TO RELATED APPLICATION

This application claims priority to Korean Patent Application No. 10-2024-0012375 filed in the Korean Intellectual Property Office on Jan. 26, 2024, the disclosure of which is incorporated herein by reference herein in its entirety.

### BACKGROUND

### 1. Field

The present disclosure relates to a receiver circuit and a method of operating the receiver circuit.

### 2. Description of Related Art

In communication systems, data are transferred in the form of analog signals, and receivers in electronic devices include analog front ends (AFEs) for interfacing between input terminals and digital signal processing circuits in order to receive analog signals and process them into digital signals inside.

Receiver circuits provided in the receivers may compensate for loss of high-frequency components by the analog front ends. However, in the analog front ends which are semiconductor circuits, ‘DC offset voltages’ are generally generated due to design errors, manufacturing process errors, package errors, and external environments.

Offset calibration on such DC offset voltages are required to drive the analog front ends, and due to the characteristics of DC offset voltages which are affected by the external environments, the analog front ends require adaptive offset calibration operations.

### SUMMARY

One or more example embodiments provide a receiver circuit capable of compensating for a DC offset voltage adaptively to the external environment, and a method of operating the receiver circuit.

One or more example embodiments provide a receiver circuit with an improved receivable frequency bandwidth, and a method of operating the receiver circuit.

According to an aspect of an example embodiment, a receiver circuit includes: a first stage circuit configured to receive a first input differential signal through a first input terminal and a second input differential signal through a second input terminal different from the first input terminal, and perform a waveform adjustment operation or amplification operation on the first and second input differential signals; a replica circuit configured to receive a common mode voltage related to the first and second input differential signals, and perform a waveform adjustment operation or amplification operation on the common mode voltage; a multiplexer that is configured to output one of an output of the first stage circuit and an output of the replica circuit as first and second intermediate differential signals based on an offset calibration enable signal; and an offset calibration logic configured to receive a digital signal generated based on the first and second intermediate differential signals, and perform an offset calibration operation based on the digital signal.

According to another aspect of an example embodiment, a receiver circuit includes: a first stage circuit, a replica circuit, and a multiplexer circuit. The first stage circuit includes: a first transistor configured to connect a first intermediate node and a first current source based on a first input differential signal at a first input terminal; and a second transistor configured to connect a second intermediate node different from the first intermediate node and the first current source based on a second input differential signal at a second input terminal different from the first input terminal. The replica circuit includes: a third transistor configured to connect the first intermediate node and a second current source based on a common mode voltage related to the first and second input differential signals; and a fourth transistor configured to connect the second intermediate node and the second current source based on the common mode voltage. The multiplexer includes: a fifth transistor which is connected between the third transistor and the first intermediate node, and is configured to operate according to an offset calibration enable signal; a sixth transistor which is connected between the fourth transistor and the second intermediate node, and is configured to operate according to the offset calibration enable signal; a seventh transistor which is connected between the first transistor and the first intermediate node, and is configured to operate according to an inversion signal corresponding to an inverse of the offset calibration enable signal; and an eighth transistor which is connected between the second transistor and the second intermediate node, and is configured to operate according to the inversion signal.

According to another aspect of an example embodiment, a receiver circuit includes: an input stage circuit including: a multiplexer configured to output a first intermediate differential signal to a first intermediate node and a second intermediate differential signal to a second intermediate node different from the first intermediate node; a first transistor including first and second gate lines extending in a first direction on an active region and spaced apart from each other in a second direction intersecting the first direction, wherein the first transistor is electrically connected to the first intermediate node; a second transistor including a third gate line extending in the first direction between the first and second gate lines, and a fourth gate line extending in the first direction on the active region and different from the third gate line, wherein the second transistor is electrically connected to the first intermediate node; a first dummy transistor including a first dummy gate line extending in the first direction between the first and third gate lines; and a second dummy transistor including a second dummy gate line extending in the first direction between the second and third gate lines; a subsequent stage circuit configured to perform a waveform adjustment operation or amplification operation on the first and second intermediate differential signals, and output first and second output differential signals; and a sense amplifier configured to sense data based on the first and second output differential signals.

According to another aspect of an example embodiment, a method of operating a receiver circuit, includes: receiving an offset calibration enable signal; selecting one of a first stage circuit configured to receive first and second input differential signals and a replica circuit configured to receive a common mode voltage related to the first and second input differential signals, based on the offset calibration enable signal; generating an offset code related to the common mode voltage; performing an offset calibration operation by providing a compensation voltage according to the offset code to the replica circuit; checking completion of the offset calibration operation; and fixing the offset code based on the offset calibration operation being completed.

### BRIEF DESCRIPTION OF DRAWINGS

The above and other aspects and features will be more apparent from the following description of embodiments with reference to the attached drawings.

FIG. 1 is a block diagram illustrating a communication system according to an example embodiment.

FIG. 2 is a block diagram illustrating a receiver circuit according to an example embodiment.

FIG. 3 is a block diagram illustrating a receiver circuit according to an example embodiment.

FIG. 4 is a circuit diagram for explaining an input stage circuit according to an example embodiment.

FIG. 5 is a layout diagram for explaining the first stage circuit and replica circuit of FIG. 4, according to an example embodiment.

FIG. 6 is a flow chart for explaining a method of operating the receiver circuit according to an example embodiment.

FIG. 7 is a timing chart for explaining an operation method of an electronic device according to an example embodiment.

FIG. 8 is a timing chart for explaining a method of operating the receiver circuit according to an example embodiment.

FIGS. 9 and 10 are drawings for explaining the method of operating the receiver circuit according to an example embodiment.

FIG. 11 is a block diagram illustrating a receiver circuit according to an example embodiment.

FIG. 12 is a block diagram illustrating an offset calibration logic according to an example embodiment.

FIG. 13 is a timing chart for explaining an operation method of an electronic device according to an example embodiment.

FIG. 14 is a drawing for explaining the calibration determination signal of FIG. 13, according to an example embodiment.

FIG. 15 is a block diagram illustrating a communication system adopting a receiver circuit according to an example embodiment.

FIG. 16 is a block diagram illustrating a communication system adopting a receiver circuit according to an example embodiment.

FIG. 17 is a timing chart for explaining an operation method of the communication system according to an example embodiment.

### DETAILED DESCRIPTION

Embodiments are described below with reference to the accompanying drawings. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

As used herein, expressions such as “at least one of,” and “at least one from among,” when preceding a list of elements, modify the entire list of elements and do not modify the individual elements of the list. For example, the expression, “at least one from among a, b, and c,” should be understood as including only a, only b, only c, both a and b, both a and c, both b and c, or all of a, b, and c.

The terms such as “module”, “unit”, “part”, and the like used in this specification are terms for indicating constituent elements for performing at least one function or operation, and these constituent elements may be implemented with hardware or software, or may be implemented with a combination of hardware and software.

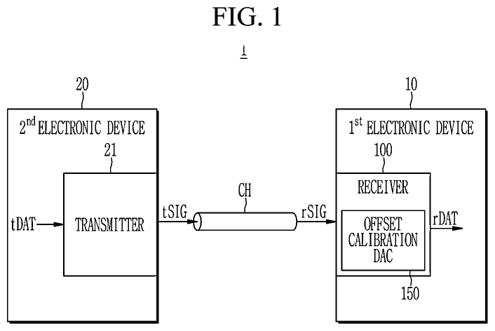

FIG. 1 is a block diagram illustrating a communication system according to an example embodiment.

Referring to FIG. 1, a communication system 1 may include a first electronic device 10 and a second electronic device 20. The first electronic device 10 may perform communication with the second electronic device 20 through a channel CH. To this end, the first electronic device 10 may include a receiver circuit 100, and the second electronic device 20 may include a transmitter circuit 21.

In some example embodiments, each of the first electronic device 10 and the second electronic device 20 may be a portable communication terminal, a personal digital assistant (PDA), a portable media player (PMP), a smart phone, or a wearable device type, or a computing device such as a personal computer, a server, a workstation, a laptop, or the like. Alternatively, each of the first electronic device 10 and the second electronic device 20 may be various hardware components included in one user device, such as a processor, a memory device, a storage device, or a control device.

In some example embodiments, the channel CH may be a signal line (i.e., a wire communication channel) or a radio communication channel for electrically connecting the first electronic device 10 and the second electronic device 20. In this regard, each of the transmitter circuit 21 and the receiver circuit 100 may transmit and receive various types of signals such as electrical signals, optical signals, radio signals, and transmit and receive analog signals. Hereinafter, for ease of explanation, it is assumed that each of the transmitter circuit 21 and the receiver circuit 100 operates on the basis of electrical signals.

The transmitter circuit 21 may receive transmission data tDAT required to be transmitted, and output a transmission signal tSIG corresponding to the transmission data tDAT. The transmission data tDAT may be generated inside the second electronic device 20 and include (i.e., indicate) information to be transmitted to the first electronic device 10. The transmitter circuit 21 may transmit the transmission signal tSIG to the receiver circuit 100 through the channel CH. While the transmission signal tSIG is transferred to the receiver circuit 100 through the channel CH, it may be changed to a reception signal rSIG.

The receiver circuit 100 may receive the reception signal rSIG through the channel CH. The receiver circuit 100 may output reception data rDAT based on the reception signal rSIG. The reception data rDAT may include information corresponding to the information included in the transmission data tDAT.

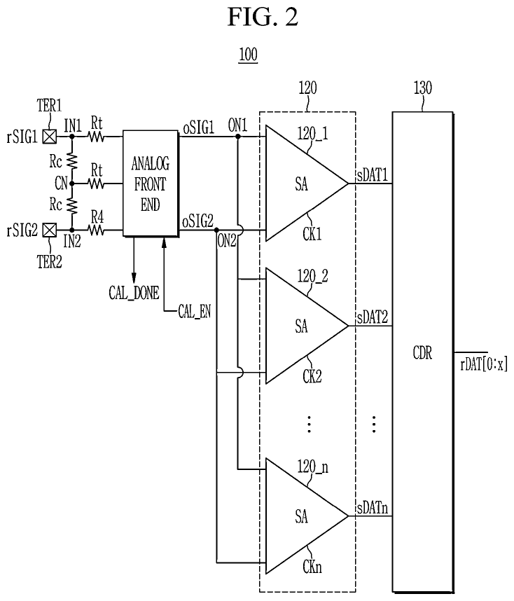

In some example embodiments, the information transmitted by the transmitter circuit 21 and the information received by the receiver circuit 100 may be different from each other. While the transmission signal tSIG passes through the channel CH, distortion of the signal may occur due to noise, and thus an error or malfunction may be caused in the first electronic device 10. The receiver circuit 100 may include an analog front end (i.e., an analog front end circuit) 110 of FIG. 2 to remove noise from the reception signal rSIG and appropriately output the reception data rDAT.

The first electronic device 10 may further include a master device for the receiver circuit 100. The master device may perform various processing operations related to control on the receiver circuit 100. For example, the master device may be at least one of processors such as central processing units (CPUs), graphics processing units (GPUs), neural processing units (NPUs), and data processing units (DPUs), or may be a combination thereof. In an example embodiment, the master device may include a single-core processor or a multi-core processor.

The master device may provide an enable signal for controlling the operation mode of the receiver circuit 100, and the receiver circuit 100 may provide a return signal related to the operation according to the enable signal to the master device. For example, the master device may provide an offset calibration enable signal to the receiver circuit 100 to make the receiver circuit 100 perform an offset calibration operation. The receiver circuit 100 may perform the offset calibration operation and provide an offset calibration completion signal to the master device in response to completion of the offset calibration operation.

FIG. 2 is a block diagram illustrating a receiver circuit according to an example embodiment.

The receiver circuit 100 may include the analog front end 110, a sense amplifier (e.g., sense amplifier circuit) 120, and a clock-data recovery (CDR) circuit 130.

The analog front end 110 may be connected to first input and second input nodes IN1 and IN2, which are connected to first and second input terminals TER1 and TER2, through terminal resistors Rt. The analog front end 110 may be connected to a first common node CN1, disposed between the first input and second input nodes IN1 and IN2, through a terminal resistor Rt. The first common node CN1 may be disposed between common mode resistors Rc, which are disposed in series between the first input and second input nodes IN1 and IN2 and have the same resistance value. In some example embodiments, at the first common node CN1, a DC voltage component related to first and second input differential signals rSIG1 and rSIG2 may be generated.

In some example embodiments, between the analog front end 110 and the first and second input terminals TER1 and TER2, no capacitive element may be disposed. For example, any switch transistor which operates in response to the operation mode of the analog front end 110 may not be disposed between the analog front end 110 and the first and second input terminals TER1 and TER2.

The analog front end 110 may receive the first and second input differential signals rSIG1 and rSIG2, which are reception signals (reference symbol “rSIG” in FIG. 1), from the first and second input terminals TER1 and TER2, and eliminate/reduce distortion of the channel (reference symbol “CH” in FIG. 1). The analog front end 110 may filter noise received from the channel (reference symbol “CH” in FIG. 1), and provide first and second output differential signals oSIG1 and oSIG2 to the sense amplifier 120 by outputting them to first and second output nodes ON1 and ON2.

The analog front end 110 may perform an offset calibration operation on a common mode voltage, which is a DC voltage component that is generated at the first common node CN1, on the basis of an offset calibration enable signal CAL_EN. The analog front end 110 may output an offset calibration completion signal CAL_DONE depending on whether the offset calibration operation has been completed. A detailed description of the offset calibration operation will be made below.

The analog front end 110 is a semiconductor circuit, and may generate a DC offset voltage. The receiver circuit 100 according to an example embodiment may compensate for the DC offset voltage adaptively to the operation environment of the first electronic device (reference symbol “10” in FIG. 1) and a change in the external environment such as channel (reference symbol “CH” in FIG. 1) change, through an offset calibration operation of the analog front end 110.

The sense amplifier 120 may include first to n-th sense amplifiers 120_1 to 120_n, wherein n is an integer equal to or greater than 2. The first to n-th sense amplifiers 120_1 to 120_n may receive the first and second output differential signals oSIG1 and oSIG2 from the first and second output nodes ON1 and ON2, respectively, perform a sampling operation on the first and second output differential signals oSIG1 and oSIG2, and output first and n-th sampling data sDAT1 to sDATn based on the sampling operation.

The first to n-th sense amplifiers 120_1 to 120_n may perform sampling operations on the basis of first to n-th clock signals CK1 to CKn different from one another in edge timings, and output the first and n-th sampling data sDAT1 to sDATn. For example, the rising edge timings of at least some of the first and n-th sampling data sDAT1 to sDATn may be different from one another. In some example embodiments, each of the first to n-th sense amplifiers 120_1 to 120_n may be a sense amplifier flip-flop as a latch type sense amplifier; however, example embodiments are not limited thereto.

By operating as a comparator, the sense amplifier 120 may perform sampling on the first and second output differential signals oSIG1 and oSIG2 at a predetermined time point and output the first and n-th sampling data sDAT1 to sDATn which are digital data.

The clock-data recovery circuit 130 according to an example embodiment may perform a serializing and deserializing (SerDes) operation on the basis of the first and n-th sampling data sDAT1 to sDATn, and output reception data rDAT [0:x] having a plurality of bits (x is equal to or greater than 1).

In some example embodiments, the clock-data recovery circuit 130 may synchronize the rising edges of the first and n-th sampling data sDAT1 to sDATn and the rising edges of the clock signals by eliminating the phase differences between the first and n-th sampling data sDAT1 to sDATn and the clock signals.

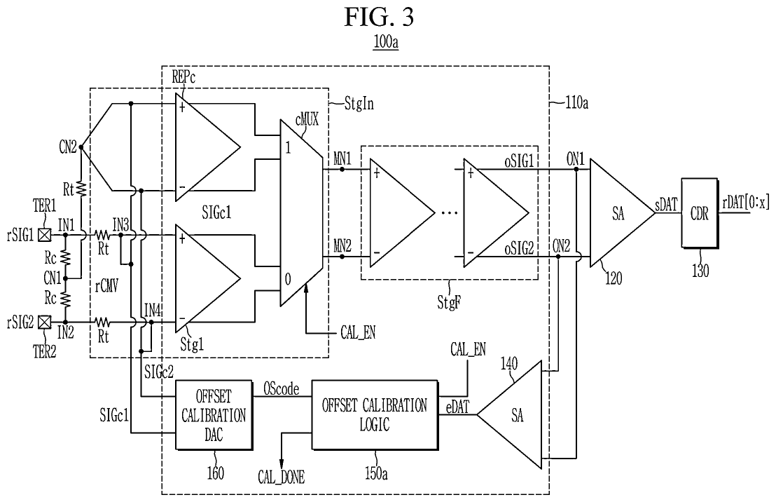

FIG. 3 is a block diagram illustrating a receiver circuit according to an example embodiment. A receiver circuit 100a of FIG. 3 and the receiver circuit 100 of FIG. 2 may correspond to each other, and the components of them may correspond to each other. FIG. 3 shows the components of an analog front end 110a, and hereinafter, for ease of explanation, the receiver circuit 100a will be described with a focus on the analog front end 110a.

Referring to FIG. 3, the analog front end 110a may include an input stage circuit StgIn, a subsequent stage circuit StgF, an error sense amplifier 140, an offset calibration logic (i.e., offset calibration logic circuit) 150a, and an offset calibration digital-to-analog converter (DAC) 160. The analog front end 110a may adjust or amplify the waveforms of the first and second input differential signals rSIG1 and rSIG2 over a plurality of operations, by the input stage circuit StgIn and the subsequent stage circuit StgF.

The input stage circuit StgIn may include a first stage circuit Stg1, a replica circuit REPc, and a multiplexer cMUX. The input stage circuit StgIn may receive the first and second input differential signals rSIG1 and rSIG2 through third input and fourth input nodes IN3 and IN4. The input stage circuit StgIn may receive a common mode voltage rCMV related to the first and second input differential signals rSIG1 and rSIG2 through a second common node CN2.

In some example embodiments, between the input stage circuit StgIn and the first and second input terminals TER1 and TER2, no capacitive element may be disposed. In some example embodiments, between the third input node IN3, the fourth input node IN4, and the second common node CN2 and the first input node IN1, the second input node IN2, and the first common node CN1, resistive elements may be disposed and no capacitive element may be disposed.

In some example embodiments, the input stage circuit StgIn may adjust and amplify the waveforms of the first and second input differential signals rSIG1 and rSIG2 in a normal operation, and output the differential signals as the operation results to first and second intermediate nodes MN1 and MN2. The input stage circuit StgIn may adjust and amplify the waveform of the common mode voltage rCMV in the offset calibration operation, and output a differential signal as the operation result to the first and second intermediate nodes MN1 and MN2.

The third input node IN3 may be connected to the first input node IN1 through a terminal resistor Rt, and the fourth input node IN4 may be connected to the second input node IN2 through a terminal resistor Rt, and the second common node CN2 may be connected to the first common node CN1 through a terminal resistor Rt.

In some example embodiments, the first stage circuit Stg1 may serve as an equalizer or an amplifier. For example, the equalizer may include a continuous time linear equalizer (CTLE). The CTLE may correct a signal distortion due to high-frequency attenuation of a signal caused by a channel. For example, the amplifier may include a variable gain amplifier (VGA). The VGA may amplify an input signal with a variable gain. The first stage circuit Stg1 may receive the first and second input differential signals rSIG1 and rSIG2, and adjust or amplify the waveforms of the first and second input differential signals rSIG1 and rSIG2, and transmit them to the multiplexer cMUX.

The replica circuit REPc may serve as a replica circuit related to the first stage circuit Stg1, and receive the common mode voltage rCMV, for example through another branch. In some example embodiments, the replica circuit REPc and the first stage circuit Stg1 may include identical components.

In some example embodiments, the replica circuit REPc may include some components in the first stage circuit Stg1.

The replica circuit REPc may serve as an equalizer or an amplifier depending on the configuration of the first stage circuit Stg1. The replica circuit REPc may receive the branched common mode voltage rCMV, and adjust or amplify the waveform of the common mode voltage rCMV, and transmit it to the multiplexer cMUX.

The multiplexer cMUX may determine the operations of the analog front end 110a and the input stage circuit StgIn on the basis of the offset calibration enable signal CAL_EN. The multiplexer cMUX may output one of the output of the first stage circuit Stg1 and the output of the replica circuit REPc, as an intermediate differential signal, to the first and second intermediate nodes MN1 and MN2 on the basis of the offset calibration enable signal CAL_EN. The output intermediate differential signal may be provided to the subsequent stage circuit StgF.

In some example embodiments, the multiplexer cMUX may receive the offset calibration enable signal CAL_EN having a high logic value, and perform an offset calibration operation. In the offset calibration mode, the multiplexer cMUX may output the output of the replica circuit REPc as an intermediate differential signal to the first and second intermediate nodes MN1 and MN2.

In some example embodiments, the multiplexer cMUX may receive the offset calibration enable signal CAL_EN having a low logic value, and perform a normal operation based on the low logic value of the offset calibration enable signal CAL_EN. In the normal operation, the multiplexer cMUX may output the output of the first stage circuit Stg1 as an intermediate differential signal to the first and second intermediate nodes MN1 and MN2. In some example embodiments, the multiplexer cMUX may receive the inversion signal of the offset calibration enable signal CAL_EN and perform a normal operation.

The subsequent stage circuit StgF may include at least one stage circuit. Each of the at least one stage circuit may serve as an equalizer or an amplifier. The subsequent stage circuit StgF may adjust or amplify the waveform of the intermediate differential signal output from the input stage circuit StgIn over a plurality of stages, and output the first and second output differential signals oSIG1 and oSIG2 to the first and second output nodes ON1 and ON2.

The error sense amplifier 140 may receive the first and second output differential signals oSIG1 and oSIG2 from the first and second output nodes ON1 and ON2. The error sense amplifier 140 may serve as a comparator, and perform a sampling operation on the first and second output differential signals oSIG1 and oSIG2, and output error data eDAT which is a digital signal. The output error data eDAT may be provided to the offset calibration logic 150a. In some example embodiments, the error sense amplifier 140 may asynchronously perform sampling on the differential signals output to the first and second output nodes ON1 and ON2.

In some example embodiments, the offset calibration logic 150a may output an offset code OScode which is sequentially incremented or decremented, on the basis of the offset calibration enable signal CAL_EN. The output offset code OScode may be provided to the offset calibration DAC 160.

For example, the offset calibration logic 150a may receive the offset calibration enable signal CAL_EN having the high logic value. In response to the high logic value of the offset calibration enable signal CAL_EN, the offset code OScode may be sequentially incremented in a predetermined order rising from a minimum value of 000000000 to a maximum value of 111111111. In some example embodiments, in response to the high logic value of the offset calibration enable signal CAL_EN, the offset code OScode may be decremented in a predetermined order. In the corresponding examples, it is shown that the number of bits of the offset code is 9; however, the number of bits is an example, and example embodiments are not limited thereto.

In some example embodiments, the offset calibration logic 150a may fix the offset code OScode and complete the offset calibration operation in response to a logical transition of the error data eDAT. The offset calibration logic 150a may output the offset calibration completion signal CAL_DONE in response to the completion of the offset calibration operation.

For example, the offset calibration logic 150a may log the offset code OScode at a rising edge of the error data eDAT, and log the offset codes OScode at a falling edge of the error data eDAT after the rising edge. In some example embodiments, the offset calibration logic 150a may fix and output an offset code OScode corresponding to the median between the offset code OScode at the rising edge of the error data eDAT and the offset code OScode at the falling edge of the error data eDAT, thereby completing the offset calibration operation.

The offset calibration DAC 160 may receive the offset code OScode from the offset calibration logic 150a, and output first and second compensation signals SIGc1 and SIGc2. The output first and second compensation signals SIGc1 and SIGc2 may be provided to the third and fourth input nodes IN3 and IN4 and the second common node CN2. In some example embodiments, the first and second compensation signals SIGc1 and SIGc2 may be signals for eliminating a DC offset voltage and include compensation voltages. The offset calibration DAC 160 may perform an offset calibration operation by providing the first and second compensation signals SIGc1 and SIGc2 to the input stage circuit StgIn.

In some example embodiments, the offset calibration DAC 160 may be a digital-to-analog converter circuit, and may receive the offset code OScode which is a digital signal and output the first and second compensation signals SIGc1 and SIGc2 which are compensation voltages corresponding to the received offset code OScode. In some example embodiments, the first and second compensation signals SIGc1 and SIGc2 may be DC voltages.

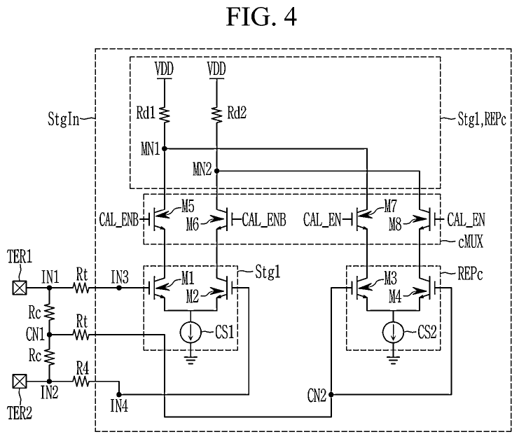

FIG. 4 is a circuit diagram for explaining the input stage circuit according to an example embodiment.

Referring to FIG. 4, the input stage circuit StgIn may include the first stage circuit Stg1, the replica circuit REPc, and the multiplexer cMUX.

The first stage circuit Stg1 may include first and second transistors M1 and M2, a first current source CS1, a first resistor Rd1, and a second resistor Rd2.

The first stage circuit Stg1 may be connected to the first input and second input nodes IN1 and IN2, which are connected to the first and second input terminals TER1 and TER2, through the terminal resistors Rt. The gate terminal of the first transistor M1 may be connected to the third input node IN3, and a terminal resistor Rt may be connected between the third input node IN3 and the first input node IN1. The source terminal of the first transistor M1 may be connected to the first current source CS1, and the drain terminal of the first transistor M1 may be connected to the source terminal of a fifth transistor M5 of the multiplexer cMUX. In some example embodiments, the first transistor M1 may be an n-channel metal-oxide semiconductor (NMOS) transistor.

The gate terminal of the second transistor M2 may be connected to the fourth input node IN4, and a terminal resistor Rt may be connected between the fourth input node IN4 and the second input node IN2. The source terminal of the second transistor M2 may be connected to the first current source CS1, and the drain terminal of the second transistor M2 may be connected to the source terminal of a sixth transistor M6 of the multiplexer cMUX. In some example embodiments, the second transistor M2 may be an NMOS transistor.

One end of the first resistor Rd1 may be connected to a power voltage VDD, and the other end of the first resistor Rd1 may be connected to the first intermediate node MN1. The other end of the first resistor Rd1 may be connected to the fifth transistor M5 of the multiplexer cMUX through the first intermediate node MN1.

One end of the second resistor Rd2 may be connected to the power voltage VDD, and the other end of the second resistor Rd2 may be connected to the second intermediate node MN2. The other end of the second resistor Rd2 may be connected to the sixth transistor M6 of the multiplexer cMUX through the second intermediate node MN2.

In some example embodiments, the first stage circuit Stg1 may serve as an amplifier. For example, when the fifth and sixth transistors M5 and M6 of the multiplexer cMUX are turned on, the signals input to the gate terminals of the first and second transistors M1 and M2 may be amplified and output to the first and second intermediate nodes MN1 and MN2.

In the drawings, it is shown that the first stage circuit Stg1 is an amplifier circuit; however, example embodiments are not limited thereto, and the first stage circuit may be changed depending on example embodiments. In an example embodiment, the first stage circuit Stg1 may be an equalizer.

The replica circuit REPc may include third and fourth transistors M3 and M4, a second current source CS2, the first resistor Rd1, and the second resistor Rd2. The replica circuit may share the first resistor Rd1 and the second resistor Rd2 with the first stage circuit Stg1. Depending on the operation of the analog front end 110a, the connection relationship of the first to fourth transistors M1 to M4, the first resistor Rd1, and the second resistor Rd2 may be changed.

The replica circuit REPc may be connected to the first common node CN1, disposed between the first and second input nodes IN1 and IN2, through the terminal resistors Rt. The gate terminal of the third transistor M3 may be connected to the second common node CN2, and a terminal resistor Rt may be connected between the second common node CN2 and the first common node CN1. The source terminal of the third transistor M3 may be connected to the second current source CS2, and the drain terminal of the third transistor M3 may be connected to the source terminal of a seventh transistor M7 of the multiplexer cMUX. In some example embodiments, the third transistor M3 may be an NMOS transistor.

The gate terminal of the fourth transistor M4 may be connected to the second common node CN2. The source terminal of the fourth transistor M4 may be connected to the second current source CS2, and the drain terminal of the fourth transistor M4 may be connected to the source terminal of an eighth transistor M8 of the multiplexer cMUX. In some example embodiments, the fourth transistor M4 may be an NMOS transistor.

One end of the first resistor Rd1 may be connected to the power voltage VDD, and the other end of the first resistor Rd1 may be connected to the first intermediate node MN1. The other end of the first resistor Rd1 may be connected to the drain terminal of the seventh transistor M7 in the multiplexer cMUX through the first intermediate node MN1.

One end of the second resistor Rd2 may be connected to the power voltage VDD, and the other end of the second resistor Rd2 may be connected to the second intermediate node MN2. The other end of the second resistor Rd2 may be connected to the drain terminal of the sixth transistor M6 in the multiplexer cMUX through the second intermediate node MN2.

In some example embodiments, the replica circuit REPc may include components identical to those of the first stage circuit as a replica circuit of the first stage circuit Stg1, and may serve as an amplifier. For example, when the seventh and eighth transistors M7 and M8 of the multiplexer cMUX are turned on, the signals input to the gate terminals of the seventh and eighth transistors M7 and M8 may be amplified and output to the first and second intermediate nodes MN1 and MN2.

The multiplexer cMUX may include the fifth to eighth transistors M5 to M8. The gate terminals of the fifth and sixth transistors M5 and M6 may receive an offset calibration enable inversion signal CAL_ENB, and the gate terminals of the seventh and eighth transistors M7 and M8 may receive the offset calibration enable signal CAL_EN. In some example embodiments, the offset calibration enable inversion signal CAL_ENB may be the inversion signal of the offset calibration enable signal CAL_EN.

The drain terminal of the fifth transistor M5 may be connected to the first intermediate node MN1, and the source terminal of the fifth transistor M5 may be connected to the drain terminal of the first transistor M1. The drain terminal of the sixth transistor M6 may be connected to the second intermediate node MN2, and the source terminal of the sixth transistor M6 may be connected to the drain terminal of the second transistor M2.

The drain terminal of the seventh transistor M7 may be connected to the first intermediate node MN1, and the source terminal of the seventh transistor M7 may be connected to the drain terminal of the third transistor M3. The drain terminal of the eighth transistor M8 may be connected to the second intermediate node MN2, and the source terminal of the eighth transistor M8 may be connected to the drain terminal of the second transistor M2. In some example embodiments, the fifth to eighth transistors M5 to M8 may be NMOS transistors.

The multiplexer cMUX may connect the first and second transistors M1 and M2 and the first and second intermediate nodes MN1 and MN2 or may connect the third and fourth transistors M3 and M4 and the first and second intermediate nodes MN1 and MN2, in response to the offset calibration enable signal CAL_EN.

For example, the multiplexer cMUX may interrupt the electrical connection between the first and second transistors M1 and M2 and the first and second intermediate nodes MN1 and MN2, and electrically connect the third and fourth transistors M3 and M4 and the first and second intermediate nodes MN1 and MN2, in response to the high logic value of the offset calibration enable signal CAL_EN.

Also, the multiplexer cMUX may electrically connect the first and second transistors M1 and M2 and the first and second intermediate nodes MN1 and MN2, and interrupt the electrical connection between the third and fourth transistors M3 and M4 and the first and second intermediate nodes MN1 and MN2, in response to the low logic value of the offset calibration enable signal CAL_EN.

In some example embodiments, the high logic value of the offset calibration enable signal CAL_EN may indicate an offset calibration operation of the analog front end 110a, and the low logic value of the offset calibration enable signal CAL_EN may indicate a normal operation of the analog front end 110a.

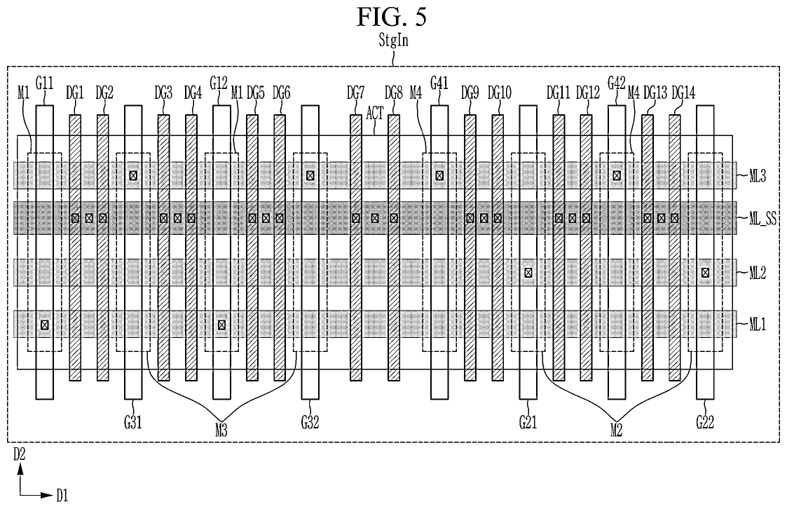

FIG. 5 is a layout diagram for explaining the first stage circuit and replica circuit of FIG. 4. Specifically, FIG. 5 may be a layout diagram related to the first to fourth transistors M1 to M4 of FIG. 4.

Referring to FIGS. 4 and 5, according to an example embodiment, the input stage circuit StgIn may be formed on a substrate, and the substrate may be doped with a P-type impurity, and may contain a semiconductor such as silicon (Si) or germanium (Ge), or a III-V compound such as GaAs, AlGaAs, InAs, InGaAs, InSb, GaSb, InGaSb, InP, GaP, InGaP, InN, GaN, InGaN, etc. In some example embodiments, the substrate may be a silicon-on-insulator (SOI) substrate or a germanium-on-insulator (GOI) substrate.

The input stage circuit StgIn may include an active region ACT, (1_1)-st to (4_2)-nd gate lines G11 to G42, and first to fourteenth dummy gate lines DG1 to DG14.

The active region ACT may be formed on the substrate, and although the drawing shows the active region ACT as being regionally distinct from the substrate, in some example embodiments, the active region ACT may be a region doped with a P-type impurity like the substrate.

On the active region ACT, each of the (1_1)-st to (4_2)-nd gate lines G11 to G42 may extend in a second direction D2. The (1_1)-st to (4_2)-nd gate lines G11 to G42 may be disposed so as to be spaced apart from each other in a first direction D1.

The (1_1)-st to (4_2)-nd gate lines G11 to G42 may be conductive electrode patterns, and may include a single layer of TIN, TiAlN, or TiAlC or a combination of single layers of TIN, TiAlN, or TiAlC in some example embodiments; however, example embodiments are not limited thereto.

In some example embodiments, the (1_1)-st gate line G11 and the (1_2)-nd gate line G12 may be connected through a first wiring line ML1 extending in the first direction D1. By the (1_1)-st gate line G11 and the (1_2)-nd gate line G12, a first transistor M1 may be formed in the active region ACT. The first transistor M1 may correspond to the first transistor M1 of FIG. 4.

In the drawing, it is shown that the (1_1)-st gate line G11 and the (1_2)-nd gate line G12 are connected through the first wiring line ML1 extending on the gate lines; however, example embodiments are not limited thereto. In an example embodiment, the (1_1)-st gate line G11 and the (1_2)-nd gate line G12 may form one finger structure.

The (2_1)-st gate line G21 and the (2_2)-nd gate line G22 may be connected through a second wiring line ML2 extending in the first direction D1. By the (2_1)-st gate line G21 and the (2_2)-nd gate line G22, a second transistor M2 may be formed in the active region ACT. The second transistor M2 may correspond to the second transistor M2 of FIG. 4.

The (3_1)-st gate line G31 and the (3_2)-nd gate line G32 may be connected through a third wiring line ML3 extending in the first direction D1. By the (3_1)-st gate line G31 and the (3_2)-nd gate line G32, a third transistor M3 may be formed on the active region ACT. The third transistor M3 may correspond to the third transistor M3 of FIG. 4.

The (4_1)-st gate line G41 and the (4_2)-nd gate line G42 may be connected through the third wiring line ML3 extending in the first direction D1. By the (4_1)-st gate line G41 and the (4_2)-nd gate line G42, a fourth transistor M4 may be formed in the active region ACT. The fourth transistor M4 may correspond to the fourth transistor M4 of FIG. 4.

In some example embodiments, the (1_1)-st gate line G11 which is a partial gate line of the first transistor M1 and the (1_2)-nd gate line G12 may be disposed alternately with the (3_1)-st gate line G31 which is a partial gate line of and the third transistor M3 and the (3_2)-nd gate line G32 in the first direction D1 on the active region ACT.

Referring to FIG. 5 as an example, the (3_1)-st gate line G31 may be disposed between the (1_1)-st gate line G11 and the (1_2)-nd gate line G12, and the (1_2)-nd gate line G12 may be disposed between the (3_1)-st gate line G31 and the (3_2)-nd gate line G32.

In some example embodiments, the (2_1)-st gate line G21 which is a partial gate line of the second transistor M2, and the (2_2)-nd gate line G22 may be disposed alternately with the (4_1)-st gate line G41 which is a partial gate line of the fourth transistor M4 and the (4_2)-nd gate line G42 in the first direction D1 on the active region ACT.

Referring to FIG. 5 as an example, the (2_1)-st gate line G21 may be disposed between the (4_1)-st gate line G41 and the (4_2)-nd gate line G42, and the (4_2)-nd gate line G42 may be disposed between the (2_1)-st gate line G21 and the (2_2)-nd gate line G22.

The components of the first stage circuit Stg1 and the replica circuit REPc may be disposed together in the same active region ACT, and the components corresponding to each other may be disposed alternately with each other, whereby it is possible to reduce design errors and manufacturing process errors of the first stage circuit Stg1 and the replica circuit REPc.

For example, the partial gate lines of the first transistor M1 of the first stage circuit Stg1 and the third transistor M3 of the replica circuit REPc corresponding to each other may be alternately disposed in the first direction D1 as shown in FIG. 5, whereby it is possible to reduce errors in functions, designs, processes, and the like between the first stage circuit Stg1 and the replica circuit REPc.

Through the layout arrangement of the first to fourth transistors M1 to M4 as shown in FIG. 5, the replica circuit REPc according to example embodiment may reduce the performance difference as a replica circuit related to the first stage circuit Stg1.

Each of the first to fourteenth dummy gate lines DG1 to DG14 may extend in the second direction D2 on the active region ACT. The first to fourteenth dummy gate lines DG1 to DG14 may be disposed so as to be spaced apart from each other in the first direction D1 on the active region ACT.

The first and second dummy gate lines D1 and D2 may be disposed so as to be spaced apart from each other in the first direction D1 between the (1_1)-st gate line G11 and the (3_1)-st gate line G31. The third and fourth dummy gate lines D3 and D4 may be disposed so as to be spaced apart from each other in the first direction D1 between the (3_1)-st gate line G31 and the (1_2)-nd gate line G12. The fifth and sixth dummy gate lines D5 and D6 may be disposed so as to be spaced apart from each other in the first direction D1 between the (1_2)-nd gate line G12 and the (3_2)-nd gate line G32. The seventh and eighth dummy gate lines D7 and D8 may be disposed so as to be spaced apart from each other in the first direction D1 between the (3_2)-nd gate line G32 and the (4_1)-st gate line G41. The ninth and tenth dummy gate lines D9 and D10 may be disposed so as to be spaced apart from each other in the first direction D1 between the (4_1)-st gate line G41 and the (2_1)-st gate line G21. The eleventh and twelfth dummy gate lines D11 and D12 may be disposed so as to be spaced apart from each other in the first direction D1 between the (2_1)-st gate line G21 and the (4_2)-nd gate line G42. The thirteenth and fourteenth dummy gate lines D13 and D14 may be disposed so as to be spaced apart from each other in the first direction D1 between the (4_2)-nd gate line G42 and the (2_2)-nd gate line G22.

In some example embodiments, through a ground line ML_SS extending in the first direction D1, a ground voltage may be applied between each of the first to fourteenth dummy gate lines DG1 to DG14 and the first and second dummy gate lines D1 and D2, between each dummy gate line and the third and fourth dummy gate lines D3 and D4, between each dummy gate line and the fifth and sixth dummy gate lines D5 and D6, between each dummy gate line and the seventh and eighth dummy gate lines D7 and D8, between each dummy gate line and the ninth and tenth dummy gate lines D9 and D10, between each dummy gate line and the eleventh and twelfth dummy gate lines D11 and D12, between each dummy gate line and the thirteenth and fourteenth dummy gate lines D13 and D14. In some example embodiments, the dummy gate lines and some regions in the active region ACT between the dummy gate lines may be connected through the ground line ML_SS.

On the active region ACT, dummy transistors may be formed using the first to fourteenth dummy gate lines DG1 to DG14, respectively. In some example embodiments, by the ground voltage application of the ground line ML_SS, the source terminals and gate terminals of the dummy transistors may be grounded.

By the ground voltage of the dummy transistors, circuit elements corresponding to each other may be separated from each other and be driven during an offset calibration operation and a normal operation to be described below, even if a plurality of partial gate lines is alternately disposed in one active region ACT.

In FIG. 5, each of the (1_1)-st to (4_2)-nd gate lines G11 to G42 and the first to fourteenth dummy gate lines DG1 to DG14 is shown as a single-gate structure; however, example embodiments are not limited thereto, and may have a multi-finger gate structure in some example embodiments.

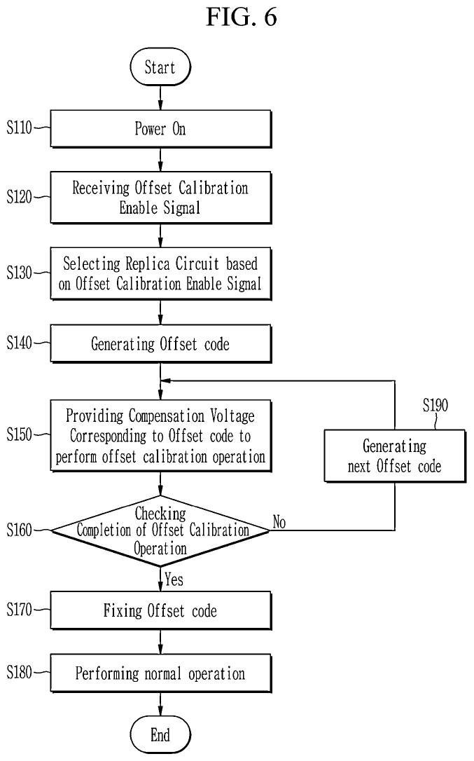

FIG. 6 is a flow chart for explaining a method of operating the receiver circuit according to example embodiment.

Referring to FIGS. 1, 2, and 6, the receiver circuit 100 may be powered on (S110).

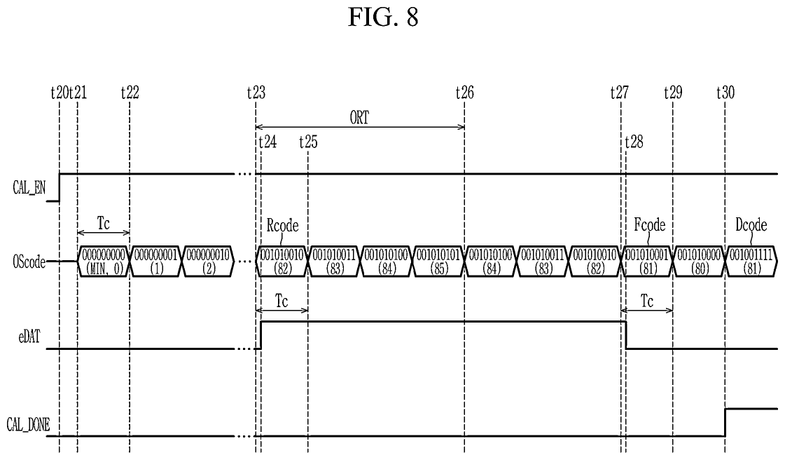

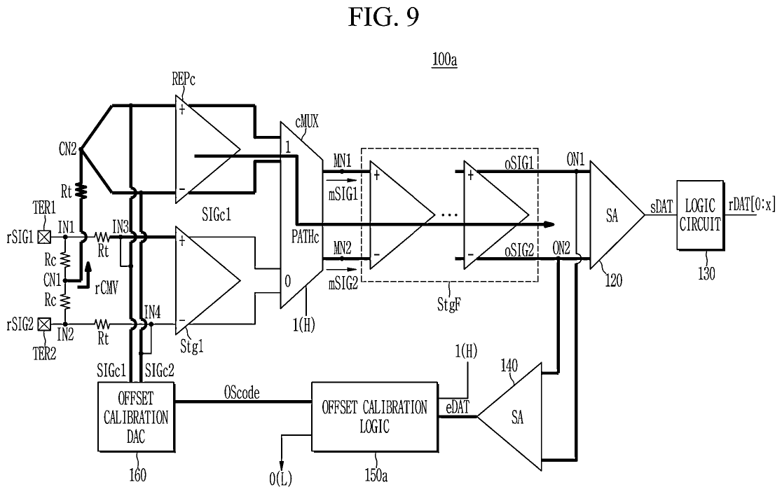

In some example embodiments, operation S110 may be performed in a wafer test stage, a final test stage, or a power-on-reset (POR) stage. In this regard, the receiver circuit 100 may be powered on and reset. Thereafter, the receiver circuit 100 may perform an offset calibration operation. The offset calibration operation will be described below in detail with reference to FIGS. 8 and 9.

After the receiver circuit 100 is powered on, it may receive the offset calibration enable signal CAL_EN (S120).

In some example embodiments, the receiver circuit 100 may receive the offset calibration enable signal CAL_EN from the master device in the first electronic device 10.

In some example embodiments, the receiver circuit 100 may receive the offset calibration enable signal CAL_EN in a runtime situation of the first electronic device 10 and also immediately after power on. When the receiver circuit 100 receives the offset calibration enable signal CAL_EN in a situation as mentioned above, the receiver circuit 100 may temporarily stop a normal operation and perform an offset calibration operation according to the offset calibration enable signal CAL_EN.

The analog front end 110 may select the replica circuit REPc on the basis of the offset calibration enable signal CAL_EN (S130).

Referring to FIG. 3 as an example, the analog front end 110a may select the replica circuit REPc on the basis of the offset calibration enable signal CAL_EN having the high logic value. The output of the replica circuit REPc may be provided to the first and second intermediate nodes MN1 and MN2, and provided to the subsequent stage circuit StgF.

The analog front end 110 may generate an offset code on the basis of the offset calibration enable signal CAL_EN (S140).

Referring to FIG. 3 as an example, the offset calibration logic 150a may receive the offset calibration enable signal CAL_EN having the high logic value, and generate an offset code OScode. A detailed description of the output of the offset code OScode will be made below with reference to FIG. 8.

In the drawing, operation S130 and operation S140 are shown as being distinct from each other; however, example embodiments are not limited thereto, and in an example embodiment, operation S130 and operation S140 may be simultaneously performed.

The analog front end 110 may provide a compensation voltage corresponding to the offset code OScode to perform an offset calibration operation (S150).

Referring to FIG. 3 as an example, the offset calibration DAC 160 may provide first and second compensation signals SIGc1 and SIGc2 corresponding to the offset code OScode, to the replica circuit REPc.

The analog front end 110 may check completion of the offset calibration operation (S160).

Referring to FIG. 3 as an example, the offset calibration logic 150a may check completion of the offset calibration operation through output of a digital signal according to the application of the first and second compensation signals SIGc1 and SIGc2. In some example embodiments, the offset calibration logic 150a may check completion of the offset calibration operation through output of error data eDAT according to the application of the first and second compensation signals SIGc1 and SIGc2.

When it is determined that the offset calibration operation has been completed, the analog front end 110 may fix the offset code (S170).

Referring to FIG. 3 as an example, when the offset calibration logic 150a determines that the offset calibration operation has been completed, the offset calibration logic 150a may output the fixed offset code OScode. Accordingly, the offset calibration DAC 160 may output the fixed first and second compensation signals SIGc1 and SIGc2. In some example embodiments, the offset calibration logic 150a may output the offset calibration completion signal CAL_DONE in response to the completion of the offset calibration operation.

The analog front end 110 may perform a normal operation (S180). For example, the normal operation may be performed based on the fixed offset code OScode.

Referring to FIG. 3 as an example, the offset calibration DAC 160 may provide the fixed first and second compensation signals SIGc1 and SIGc2 to the first stage circuit Stg1, and the analog front end 110a may select the first stage circuit Stg1 on the basis of the offset calibration enable signal CAL_EN having the low logic value. The output of the first stage circuit Stg1 may be provided to the first and second intermediate nodes MN1 and MN2, and provided to the subsequent stage circuit StgF.

When it is not determined that the offset calibration operation has been completed, the analog front end 110 may generate a next offset code on the basis of the predetermined order (S190).

Referring to FIG. 3 as an example, when the offset calibration logic 150a determines that the offset calibration operation has not been completed, the offset calibration logic 150a may generate a next offset code OScode on the basis of the predetermined order. Thereafter, operation S150, operation S160, and operation S190 may be repeatedly performed until a determination is made that the offset calibration operation has been completed.

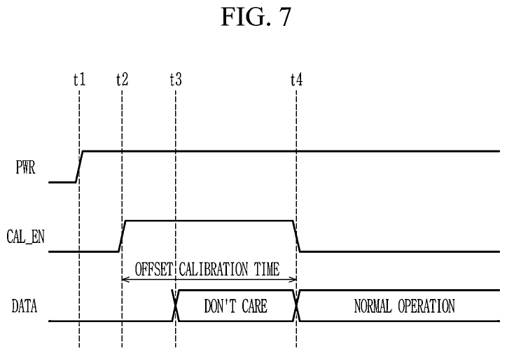

FIG. 7 is a timing chart for explaining an operation method of an electronic device according to an example embodiment.

Referring to FIGS. 1, 2, and 7, the receiver circuit 100 may be powered on and perform an offset calibration operation in an initial operation. In some example embodiments, the initial operation may be referred to as a power-up operation or a power-on-reset (POR) operation.

At a time point t1, the receiver circuit 100 may be powered on.

At a time point t2, the offset calibration enable signal CAL_EN may rise from the low logic value to the high logic value. The receiver circuit 100 may start offset calibration from the time point t2. In some example embodiments, during the initial operation or the power-up operation, the receiver circuit 100 may automatically perform offset calibration.

At a time point t3, the receiver circuit 100 may receive data through a data signal DATA. The data that are received from the time point t3 to a time point t4 may be data for stabilization of the receiver circuit 100. In this regard, the data that are received from the time point t3 to the time point t4 may not be meaningful as data itself. Therefore, the section from the time point t3 to the time point t4 may be referred to as a “Don't care” section. In the drawing, it is shown that the “Don't care” section starts after the time point t2; however, in some example embodiments, the “Don't care” section may start before the time point t2.

After the time point t4, the “Don't care” section may terminate, and the receiver circuit 100 may receive meaningful data including information required to be transmitted. In this regard, the receiver circuit 100 may start a normal operation at the time point t4. The time point t4 may be a time point when the offset calibration is completed. In this regard, the offset calibration operation may be performed from the time point t2 to the time point t4. For example, the offset calibration enable signal CAL_EN may change from the high (H) logic value to the low (L) logic value at time point t4.

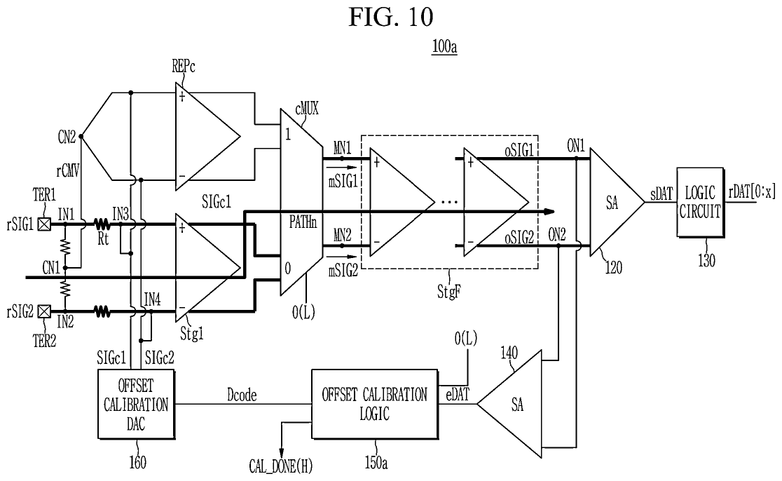

FIG. 8 is a timing chart for explaining a method of operating the receiver circuit according to an example embodiment. FIGS. 9 and 10 are drawings for explaining the method of operating the receiver circuit according to an example embodiment. FIGS. 8 and 9 are drawings for explaining an offset calibration operation of the receiver circuit 100a of FIG. 3. FIG. 10 is a drawing for explaining a normal operation of the receiver circuit 100a of FIG. 3.

Referring to FIG. 3 and FIGS. 8 to 10, at a time point t20, the receiver circuit 100a may receive the offset calibration enable signal CAL_EN having the high (H) logic value from the master device in the first electronic device 10 of FIG. 1.

On the basis of the offset calibration enable signal CAL_EN having the high (H) logic value, the multiplexer cMUX may provide the output of the replica circuit REPc to the first and second intermediate nodes MN1 and MN2, and interrupt the output of the first stage circuit Stg1. The output of the replica circuit REPc may be provided as first and second intermediate differential signals mSIG1 and mSG2 to the subsequent stage circuit StgF.

After a time point t21, the offset calibration logic 150a may output the offset code OScode, which is sequentially incremented, on the basis of the offset calibration enable signal CAL_EN having the high (H) logic value. The time interval from the time point t21 to a time point t22 may be referred to as the code period Tc of the offset code OScode. The period from the time point t21 to the time point t22 may correspond to operation S140 to operation S160 of FIG. 6.

According to an example embodiment, the offset calibration logic 150a may output an offset code OScode corresponding to a minimum value MIN, as an initial value, and the offset code OScode may be ‘000000000’. In some example embodiments, the number of bits of the offset code OScode may be 9; however, example embodiments are not limited thereto.

Referring to FIG. 9 again, the offset calibration DAC 160 may provide the first and second compensation signals SIGc1 and SIGc2 corresponding to the offset code OScode, to the replica circuit REPc. In some example embodiments, the first and second compensation signals SIGc1 and SIGc2 may be DC voltages between −1 V and 1 V, and preferably, between −0.3 V and 0.3 V. In some example embodiments, the first and second compensation signals SIGc1 and SIGc2 may be DC voltages having the same magnitude.

For example, when the number of bits of the offset code OScode is 9, the first and second compensation signals SIGc1 and SIGc2 corresponding to ‘000000000’, which is the minimum value MIN of the offset code OScode, may be a voltage signal of −256 mV. The first and second compensation signals SIGc1 and SIGc2 corresponding to ‘111111111’, which is the maximum value of the offset code OScode, may be a voltage signal of 255 mV. In some example embodiments, the difference between compensation voltages corresponding to adjacent offset codes OScode may be 1 mV. The above examples of the voltage values of the compensation signals are examples for assisting in understanding, and example embodiments are not limited thereto.

From the time point t21 to the time point t22, according to an example embodiment, the offset calibration DAC 160 may provide the first and second compensation signals SIGc1 and SIGc2 corresponding to ‘000000000’, to the replica circuit REPc.

The replica circuit REPc may receive the common mode voltage rCMV compensated with the first and second compensation signals SIGc1 and SIGc2, and adjust or amplify its waveform. The output of the replica circuit REPc may be output as the first and second intermediate differential signals mSIG1 and mSG2 to the first and second intermediate nodes MN1 and MN2.

The subsequent stage circuit StgF may receive the first and second intermediate differential signals mSIG1 and mSG2, and adjust or amplify their waveforms. The subsequent stage circuit StgF may output the first and second output differential signals oSIG1 and oSIG2 to first and second output nodes ON1 and ON2.

The error sense amplifier 140 may sense and output the error data eDAT, which are digital data, with respect to the first and second output differential signals oSIG1 and oSIG2.

The offset calibration logic 150a may check completion of the offset calibration operation through the error data eDAT according to the application of the first and second compensation signals SIGc1 and SIGc2. In some example embodiments, the offset calibration logic 150a may determine completion of the offset calibration operation on the basis of the logical transition of the error data eDAT.

In some example embodiments, the offset calibration logic 150a may determine that the offset calibration operation has been completed, when the error data eDAT transitions from the low logic value to the high logic value, when the error data eDAT transitions from the high logic value to the low logic value, or when the error data eDAT transitions from the low logic value to the high logic value and then transitions from the high logic value to the low logic value.

For example, from the time point t21 to the time point t22, any logical transition of the error data eDAT may not occur (i.e., the error data eDAT may remain constant), and thus the offset calibration logic 150a may determine that the offset calibration operation has not been completed.

After the time point t22, the offset calibration logic 150a may output the offset code OScode, which is sequentially incremented, with the code period Tc. During the offset calibration operation after the time point t22, the analog front end 110a may repeat the above-mentioned operation from the time point t21 to the time point t22, on the basis of the output offset code OScode, with the code period Tc.

At a time point t23, the offset calibration logic 150a may output an offset code OScode which results in a logical transition of the error data eDAT, as a rising code Rcode.

For example, from the time point t23 to a time point t25, the offset calibration logic 150a may output ‘001010010(82)’ as an offset code OScode to the offset calibration DAC 160. At a time point t24 between the time point t23 and the time point t25, the error data eDAT may transition from the low logic value to the high logic value, and the offset calibration logic 150a may log ‘001010010(82)’ as a rising code Rcode. ‘001010010(82)’ is an arbitrary example for explaining the offset code OScode, and example embodiments are not limited thereto.

From the time point t23 to a time point t26, the offset calibration logic 150a may sequentially increment the offset code OScode. In some example embodiments, the offset calibration logic 150a may continue to sequentially increment the offset code OScode from the rising code Rcode in proportion to an offset rise time ORT which is a predetermined time. The time interval from the time point t23 to the time point t26 may be determined in advance depending on example embodiments.

From the time point t26, the offset calibration logic 150a may stop sequentially increasing the offset code OScode, and output the offset code OScode which is sequentially decremented with the code period Tc. For example, after the time point t26, the offset calibration logic 150a may output the offset code OScode, which is sequentially decremented, on the basis of ‘001010101(85)’ output before the time point t26.

At the time point t26, the offset calibration logic 150a may output an offset code OScode for causing the logical transition of the error data eDAT, as a fall code Fcode.

For example, from the time point t26 to a time point t29, the offset calibration logic 150a may output ‘001010001(81)’ as an offset code OScode to the offset calibration DAC 160. At a time point t28 between the time point t27 and the time point t29, the error data eDAT may transition from the high logic value to the low logic value, and the offset calibration logic 150a may log ‘001010001(81)’ as the fall code Fcode. ‘001010001(81)’ is an arbitrary example for explaining the offset code OScode, and example embodiments are not limited thereto.

After the time point t28, the offset calibration logic 150a may determine that the offset calibration operation has been completed, on the basis of the logical transition of the error data eDAT.

At a time point t30, the offset calibration logic 150a may determine a fixed code Dcode on the basis of the rising code Rcode and the fall code Fcode logged. In some example embodiments, the offset calibration logic 150a may determine the rising code Rcode or the fall code Fcode as the fixed code Dcode, or may determine the median between the rising code Rcode and the fall code Fcode as the fixed code Dcode.

Referring to FIG. 8 as an example, the offset calibration logic 150a may determine ‘001010001(81)’ as the fixed code Dcode, on the basis of the rising code Rcode of ‘001010010(82)’ and the fall code Fcode of ‘001010001(81)’. The fixed code Dcode may be stored in the offset calibration DAC 160.

When determining that the offset calibration operation has been completed, the offset calibration logic 150a may output the offset calibration completion signal CAL_DONE. In some example embodiments, in response to the completion of the offset calibration operation, the receiver circuit 100a may provide the offset calibration completion signal CAL_DONE having the high logic value to the master device of the receiver circuit 100a.

After the time point t30, the offset calibration enable signal CAL_EN may transition to the low logic value. The receiver circuit 100a may perform a normal operation. The analog front end 110a may select the first stage circuit Stg1 on the basis of the offset calibration enable signal CAL_EN having the low logic value. The output of the first stage circuit Stg1 may be provided to the first and second intermediate nodes MN1 and MN2 and provided to the subsequent stage circuit StgF.

Referring to FIG. 10 again, the offset calibration DAC 160 may provide the first and second compensation signals SIGc1 and SIGc2 corresponding to the fixed code Dcode to the first stage circuit Stg1. For example, the first and second compensation signals SIGc1 and SIGc2 may vary according to the fixed code Dcode. The first and second compensation signals SIGc1 and SIGc2 corresponding to the fixed code Dcode may be compensation voltages related to the DC offset voltage.

The first stage circuit Stg1 may receive the first and second input differential signals rSIG1 and rSIG2 compensated with the first and second compensation signals SIGc1 and SIGc2 corresponding to the fixed code Dcode, and adjust or amplify their waveforms. The output of the first stage circuit Stg1 may be output as the first and second intermediate differential signals mSIG1 and mSG2 to the first and second intermediate nodes MN1 and MN2.

The subsequent stage circuit StgF may receive the first and second intermediate differential signals mSIG1 and mSG2, and adjust or amplify their waveforms based on the first and second intermediate differential signals mSIG1 and mSG2. The subsequent stage circuit StgF may output the first and second output differential signals oSIG1 and oSIG2 to the first and second output nodes ON1 and ON2.

The receiver circuit 100a may perform an effective offset calibration operation on the receiver circuit 100a adaptively to the external environment, through the arrangement of the replica circuit REPc and the multiplexer cMUX and operations on the replica circuit REPc and the multiplexer cMUX as described above.

While the receiver circuit 100a performs an effective offset calibration operation adaptively to the external environment through the arrangement of the replica circuit REPc and the multiplexer cMUX and operations on the replica circuit REPc and the multiplexer cMUX as described above, no switch transistors may be disposed between the input terminals TER1 and TER2 and the analog front end 110a.

By not disposing switch transistors between the input terminals TER1 and TER2 and the analog front end 110a, it is possible to reduce the capacitive component at the front end of the analog front end 110a, and by reducing the capacitive component, it is possible to improve the frequency bandwidth performance of the receiver circuit 100a.

The receiver circuit 100a may perform an offset calibration operation which is instantaneous and valid for the analog front end 110a by performing the offset calibration operation on the basis of the first and second output differential signals oSIG1 and oSIG2 output from the output nodes of the analog front end 110a.

In FIG. 8, the offset calibration logic 150a outputs the minimum value as the initial value; however, in some example embodiments, the offset calibration logic 150a may output an offset code OScode corresponding to the maximum value, as an initial value, and output the offset code OScode which is sequentially decremented.

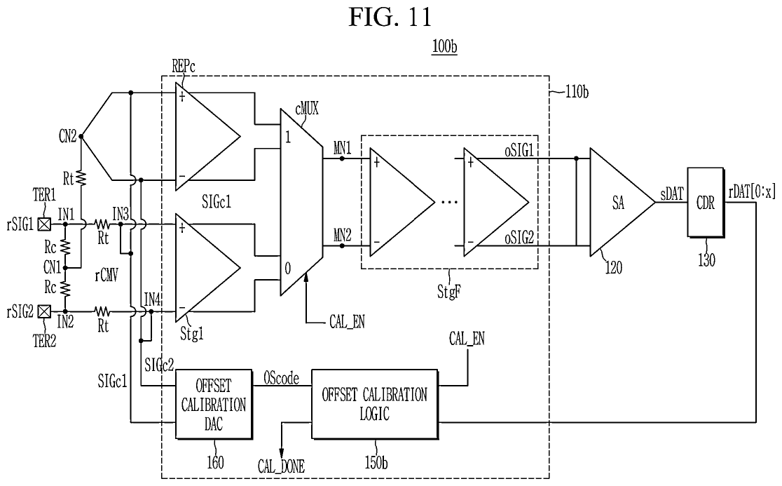

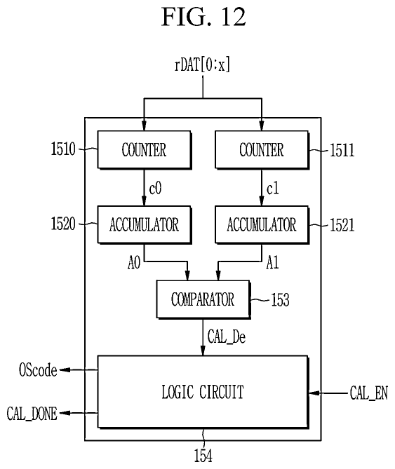

FIG. 11 is a block diagram illustrating a receiver circuit according to an example embodiment. FIG. 12 is a block diagram illustrating an offset calibration logic according to an example embodiment. A receiver circuit 100b and an analog front end 110b of FIG. 11 may correspond to the receiver circuit 100a and the analog front end 110a of FIG. 3, respectively, and will be described with a focus on the differences for ease of explanation.

Referring to FIGS. 3, 11, and 12, an offset calibration logic 150b may receive the reception data rDAT [0:x] of the clock-data recovery circuit 130 instead of the error data eDAT of FIG. 3. The offset calibration logic 150b may control an offset calibration operation of the analog front end 110b on the basis of the offset calibration enable signal CAL_EN and the reception data rDAT [0:x].

The offset calibration logic 150b may receive the reception data rDAT [0:x] for a plurality of data periods, and determine whether the offset calibration operation has been completed, on the basis of the reception data rDAT [0:x] received for the plurality of data periods.

The offset calibration logic 150b may include a 0-bit counter 1510, a 1-bit counter 1511, a 0-bit accumulator (i.e., a 0-bit accumulator circuit) 1520, a 1-bit accumulator (i.e., a 1-bit accumulator circuit) 1521, a comparator (i.e., a comparator circuit) 153, and a logic circuit 154.

According to an example embodiment, the 0-bit counter 1510 may count the bits of 0 indicating the low logic value from the reception data rDAT [0:x], and output the 0-bit count value c0. According to an example embodiment, the 1-bit counter 1511 may count the bits of 1 indicating the high logic value from the reception data rDAT [0:x], and output the 1-bit count value c1.

According to an example embodiment, the 0-bit accumulator 1520 may receive the 0-bit count value c0 for a predetermined period, and calculate the low logic values of the reception data rDAT [0:x] accumulated for the predetermined period, and output the 0-bit accumulation value A0. According to an example embodiment, the 1-bit accumulator 1521 may receive the 1-bit count value c1 for a predetermined period, and calculate the high logic values of the reception data rDAT [0:x] accumulated for the predetermined period, and output the 1-bit accumulation value A1. The predetermined period may include the code period for which one offset code OScode is output.

According to an example embodiment, the comparator 153 may compare the 0-bit accumulation value A0 and the 1-bit accumulation value A1, and output a calibration determination signal CAL_De depending on the comparison result. For example, when the 1-bit accumulation value A1 is larger than the 0-bit accumulation value A0, the comparator 153 may output the calibration determination signal CAL_De having a high logic value; however, the present disclosure is not limited thereto. For example, when the 1-bit accumulation value A1 is smaller than the 0-bit accumulation value A0, the comparator 153 may output the calibration determination signal CAL_De having a low logic value; however, the present disclosure is not limited thereto.

The logic circuit 154 may output an offset code OScode, which is sequentially incremented or decremented, on the basis of the offset calibration enable signal CAL_EN. The logic circuit 154 may correspond to the offset calibration logic 150a of FIG. 3.

According to an example embodiment, the logic circuit 154 may fix the offset code OScode and complete the offset calibration operation, on the basis of a logical transition of the calibration determination signal CAL_De. The logic circuit 154 may output the offset calibration completion signal CAL_DONE in response to the completion of the offset calibration operation.

For example, the logic circuit 154 may log an offset code OScode at a rising edge of the calibration determination signal CAL_De, and log an offset code OScode at a falling edge of the calibration determination signal CAL_De after the rising edge. According to an example embodiment, the logic circuit 154 may fix and output the offset code OScode corresponding to the median between the offset code OScode at the rising edge of the calibration determination signal CAL_De and the offset code OScode at the falling edge of the calibration determination signal CAL_De, thereby completing the offset calibration operation.

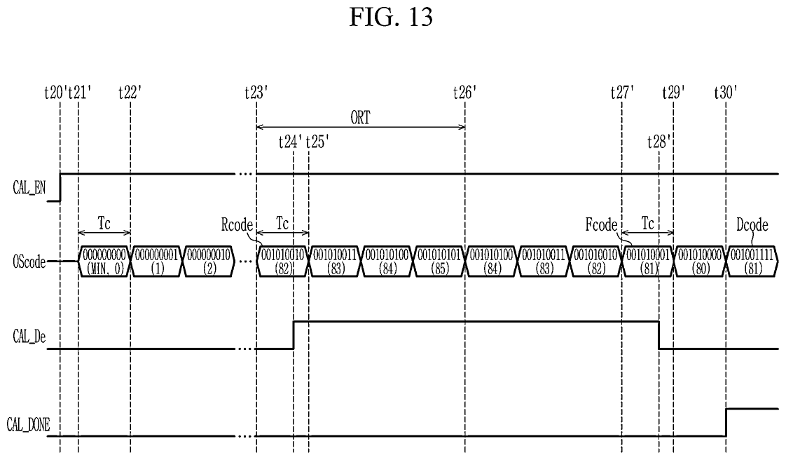

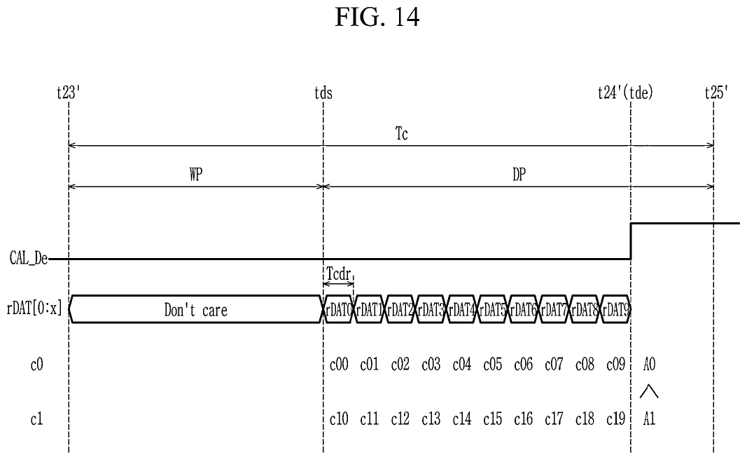

FIG. 13 is a timing chart for explaining an operation method of an electronic device according to an example embodiment. FIG. 14 is a drawing for explaining the calibration determination signal of FIG. 13. FIG. 14 is a drawing for explaining the output of the calibration determination signal CAL_De at the rising code Rcode. A time point t20′ to a time point t30′ of FIG. 13 may correspond to the time point t20 to the time point t30 of FIG. 8, respectively, and the calibration determination signal CAL_De of FIG. 13 and the error data eDAT of FIG. 8 may correspond to each other. For ease of explanation, the following description will be made with a focus on the differences.

Referring to FIGS. 11 to 14, at the time point t23′, the offset calibration logic 150b may output an offset code OScode for causing a logical transition of the calibration determination signal CAL_De, as a rising code Rcode.

After the time point t23′, during a waiting period WP of the offset calibration logic 150b, reception data rDAT [0:x] which are provided may not be meaningful to the calibration determination signal CAL_De. Thereafter, in a determination period DP, the offset calibration logic 150b may receive the reception data rDAT [0:x] for output of the calibration determination signal CAL_De for a predetermined period from a time point tds. The offset calibration logic 150b may compute the received reception data rDAT [0:x], and output the calibration determination signal CAL_De.

Referring to FIG. 14 as an example, the offset calibration logic 150b may receive 0-th to ninth reception data rDAT0 to rDAT9 for ten predetermined data periods Tcdr from the time point tds which is the determination start time point.

From the time point tds, which is the determination start time point, to a time point tde, which is a determination end time point, the 0-bit counter 1510 may output 0-th to ninth 0-bit count values c00 to c09 on the basis of the 0-th to ninth reception data rDAT0 to rDAT9. Similarly, the 1-bit counter 1511 may output 0-th to ninth 1-bit count values c10 to c19 on the basis of the 0-th to ninth reception data rDAT0 to rDAT9.

The 0-bit accumulator 1520 may calculate the 0-bit accumulation value A0 on the basis of the 0-th to ninth 0-bit count values c00 to c09, and provide the 0-bit accumulation value A0 to the comparator 153. The 1-bit accumulator 1521 may calculate the 1-bit accumulation value A1 on the basis of the 0-th to ninth 1-bit count values c10 to c19, and provide the 1-bit accumulation value A1 to the comparator 153.

The comparator 153 may compare the 0-bit accumulation value A0 and the 1-bit accumulation value A1. For example, when the 1-bit accumulation value A1 is larger than the 0-bit accumulation value A0, at the time point t24′, the comparator 153 may output the calibration determination signal CAL_De having the high logic value.

The operation of outputting the calibration determination signal CAL_De shown in FIG. 14 may be performed in every code period Tc after the time point t21′, besides the period between the time point t23′ and the time point t25′ when the rising code Rcode is output.

The receiver circuit 100b may collect and accumulate the reception data rDAT [0:x] of the clock-data recovery circuit 130 for a predetermined period and generate a signal for an offset calibration operation on the basis of them, thereby capable of improving the reliability of the offset calibration operation.

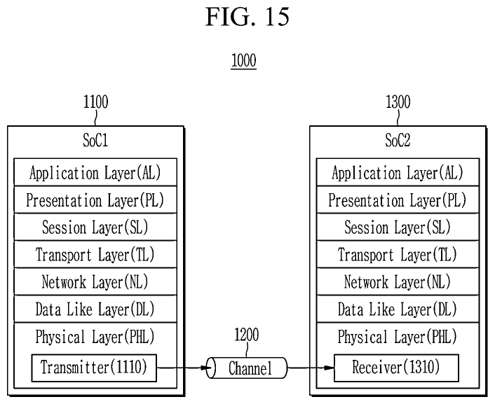

FIG. 15 is a block diagram illustrating a communication system adopting a receiver circuit according to an example embodiment.

Referring to FIG. 15, a communication system 1000 may include a first system-on-chip (SoC) 1100, a second SoC 1300, and a channel 1200.

According to an example embodiment, the first SoC 1100 and the second SoC 1300 may perform communication with each other on the basis of the 7-layer structure of the open system interconnection (OSI) model proposed in the international standard organization. For example, each of the first SoC 1100 and the second SoC 1300 may include an application layer AL, a presentation layer PL, a session layer SL, a transport layer TL, a network layer NL, a data link layer DL, and a physical layer PHY.

The individual layers of the first SoC 1100 and the second SoC 1300 corresponding to each other may logically or physically perform communication with each other. The application layer AI, the presentation layer PL, the session layer SL, the transport layer TL, the network layer NL, the data link layer DL, and the physical layer PHY of the first SoC 1100 may logically or physically perform communication with the application layer AI, the presentation layer PL, the session layer SL, the transport layer TL, the network layer NL, the data link layer DL, and the physical layer PHY of the second SoC 1300, respectively.

The physical layer PHY of the first SoC 1100 may include a transmitter circuit 1110. The transmitter circuit 1110 may be implemented inside the physical layer PHY of the first SoC 1100. The physical layer PHY of the second SoC 1300 may include a receiver circuit 1310. The receiver circuit 1310 may be implemented inside the physical layer PHY of the second SoC 1300.

The transmitter circuit 1110 of the first SoC 1100 may transmit data to the receiver circuit 1310 of the second SoC 1300 through the channel 1200. The channel 1200 may be the channel CH of FIG. 1. The receiver circuit 1310 may correspond to the receiver circuit 100 of FIG. 2, the receiver circuit 100a of FIG. 3, or the receiver circuit 100b of FIG. 11. The receiver circuit 1310 may compensate for a DC offset voltage adaptively to the external environment while improving the frequency bandwidth performance, through the operations of a replica circuit and a multiplexer.

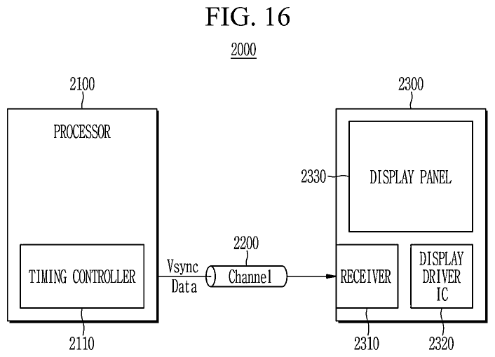

FIG. 16 is a block diagram illustrating a communication system adopting a receiver circuit according to an example embodiment.

Referring to FIG. 16, a communication system 2000 may include a processor 2100 and a display device 2300.

The communication system 2000 may be an electronic device including a display, like a small-sized electronic device such as a portable communication terminal like a smart phone, a personal digital assistant (PDA), a portable media player (PMP), a wearable device, a camera, a portable game console, an e-book reader, or a tablet PC, or a large-sized electronic product such as a TV set, or a monitor, but example embodiments are not limited thereto.

The processor 2100 may include a timing controller 2110. The processor 2100 may serve as a central processing unit for the communication system 2000. The processor may be at least one of processors such as application processors (APs), central processing units (CPUs), graphics processing units (GPUs), neural processing units (NPUs), and data processing units (DPUs), or may be a combination thereof. In an example embodiment, the processor 2100 may include a single-core processor or a multi-core processor. According to an example embodiment, the processor 2100 may control the operation of the display device 2300 through the timing controller 2110.

The timing controller 2110 may be included in the processor 2100 such that they are implemented into one chip or module; however, example embodiments are not limited thereto, and the timing controller may be implemented as a chip or module separate from the processor 2100.

According to an example embodiment, the timing controller 2110 may transmit a horizontal synchronization signal Vsync and data DATA to a receiver circuit 2310 of the display device 2300 through a channel 2200. According to an example embodiment, the horizontal synchronization signal Vsync may be a timing signal which is toggled and output with a predetermined horizontal period. The data DATA may be image data which may include video data and have a format based on the eDP standard or other standards.

The display device 2300 may include the receiver circuit 2310, a display driver circuit 2320, and a display panel 2330.

The display driver circuit 2320 may receive the timing signal such as the horizontal synchronization signal Vsync and the data DATA through the receiver circuit 2310. The display driver circuit 2320 may generate various control signals such that the display panel 2330 displays video information. According to an example embodiment, the display driver circuit 2320 may be a master device for the receiver circuit 2310.

In some example embodiments, the display panel 2330 may be implemented with an organic light emitting diode (OLED) display panel or an LED panel; however, example embodiments are not limited thereto.

The channel 2200 may be the channel CH of FIG. 1. The receiver circuit 2310 may correspond to the receiver circuit 100 of FIG. 2, the receiver circuit 100a of FIG. 3, or the receiver circuit 100b of FIG. 11.

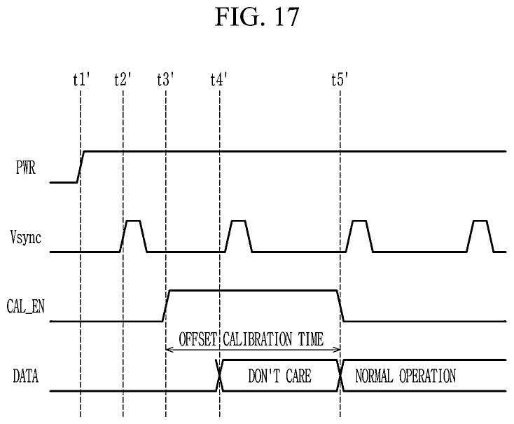

FIG. 17 is a timing chart for explaining an operation method of the communication system according to an example embodiment.

Referring to FIGS. 16 and 17, at a time point t1′, the receiver circuit 2310 may be powered on.

After a time point t2′, the receiver circuit 2310 may receive the horizontal synchronization signal Vsync which is toggled with the predetermined period.

At a time point t3′, the offset calibration enable signal CAL_EN may rise from the low logic value to the high logic value. The receiver circuit 2310 may start offset calibration from the time point t2′. According to an example embodiment, during an initial operation or a power-up operation, the receiver circuit 2310 may automatically perform offset calibration. The offset calibration enable signal CAL_EN may be the offset calibration enable signal CAL_EN of FIGS. 1 to 14.

At a time point t4′, the receiver circuit 2310 may receive the data through a data signal DATA. The data which are received from the time point t4′ to a time point t5′ may be data for stabilization of the receiver circuit 2310. In this regard, the data that are received from the time point t4′ to the time point t5′ may not be meaningful as data itself. Therefore, the section from the time point t4′ to a time point t5′ may be referred to as a “Don't care” section. In the drawing, it is shown that the “Don't care” section starts after the time point t3′; however, in some example embodiments, the “Don't care” section may start before the time point t3′.

After the time point t5′, the “Don't care” section may terminate, and the receiver circuit 2310 may receive meaningful data including information required to be transmitted. In this regard, the receiver circuit 2310 may start a normal operation at the time point t5′. The time point t5′ may be a time point when the offset calibration is completed.

From the time point t3′ to the time point t5′, the offset calibration operation described with reference to FIGS. 1 to 14 may be performed. The receiver circuit 2310 may include the replica circuit and the multiplexer of FIGS. 1 to 14, and compensate for a DC offset voltage adaptively to the external environment while improving the frequency bandwidth performance, through the operations of the replica circuit and the multiplexer.

In some example embodiments, each of the components represented by a block as illustrated in FIGS. 1-3, 9-12, 15 and 16 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing operations may employ any number of related art techniques for electronics configuration, signal processing and/or control, data processing and the like.

While aspects of embodiments have been particularly shown and described, it will be understood that various changes in form and details may be made therein without departing from the spirit and scope of the following claims.

1. A receiver circuit comprising:
a first stage circuit configured to receive a first input differential signal through a first input terminal and a second input differential signal through a second input terminal different from the first input terminal, and perform a waveform adjustment operation or amplification operation on the first and second input differential signals;
a replica circuit configured to receive a common mode voltage related to the first and second input differential signals, and perform a waveform adjustment operation or amplification operation on the common mode voltage;
a multiplexer that is configured to output one of an output of the first stage circuit and an output of the replica circuit as first and second intermediate differential signals based on an offset calibration enable signal; and
an offset calibration logic configured to receive a digital signal generated based on the first and second intermediate differential signals, and perform an offset calibration operation based on the digital signal.

2. The receiver circuit of claim 1, further comprising first and second resistors that are connected in series with each other between a first input node which is connected to the first input terminal and a second input node which is connected to the second input terminal,
wherein the common mode voltage is generated at a first common node between the first resistor and the second resistor.

3. The receiver circuit of claim 2, further comprising:
a third resistor connected between the first input node and the first stage circuit;
a fourth resistor identical to the third resistor connected between the second input node and the first stage circuit, and
a fifth resistor identical to the third resistor connected between the first common node and the replica circuit.

4. The receiver circuit of claim 1, further comprising an offset calibration digital-to-analog converter (DAC) configured to provide compensation signals corresponding to an offset code to the replica circuit,
wherein the offset calibration logic is further configured to generate the offset code.

5. The receiver circuit of claim 4, wherein the offset calibration logic is further configured to output the offset code in a fixed state based on the offset calibration operation being completed.

6. The receiver circuit of claim 5, wherein the offset calibration logic is further configured to output an offset calibration completion signal based on the offset calibration operation being completed.

7. The receiver circuit of claim 1, further comprising a subsequent stage circuit configured to perform a waveform adjustment operation or amplification operation on the first and second intermediate differential signals, and output first and second output differential signals.

8. The receiver circuit of claim 7, further comprising an error sense amplifier circuit configured to sense error data from the first and second output differential signals,
wherein the offset calibration logic is further configured to perform the offset calibration operation based on the error data.

9. The receiver circuit of claim 8, wherein the offset calibration logic is further configured to determine completion of the offset calibration operation based on a logical transition of the error data.

10. The receiver circuit of claim 7, further comprising:
a sense amplifier circuit configured to sense data from the first and second output differential signals; and
a recovery circuit configured to perform a serializing and deserializing operation on the sensed data, and output reception data indicating a plurality of bits,
wherein the offset calibration logic is further configured to perform the offset calibration operation based on the reception data.

11. The receiver circuit of claim 10, wherein the offset calibration logic comprises:
a first counter circuit configured to count low logic values of the reception data in one period and output a first count value;
a first accumulator circuit configured to accumulate the first count value for a predetermined period and output a first accumulation value;
a second counter circuit configured to count high logic values of the reception data in the one period and output a second count value;
a second accumulator circuit configured to accumulate the second count value for the predetermined period and output a second accumulation value; and
a comparator circuit configured to compare the first accumulation value and the second accumulation value.

12. The receiver circuit of claim 11, wherein the offset calibration logic is further configured to determine completion of the offset calibration operation based on an output of the comparator circuit.

13. A receiver circuit comprising:
a first stage circuit comprising:
a first transistor configured to connect a first intermediate node and a first current source based on a first input differential signal at a first input terminal; and
a second transistor configured to connect a second intermediate node different from the first intermediate node and the first current source based on a second input differential signal at a second input terminal different from the first input terminal;
a replica circuit comprising:
a third transistor configured to connect the first intermediate node and a second current source based on a common mode voltage related to the first and second input differential signals; and
a fourth transistor configured to connect the second intermediate node and the second current source based on the common mode voltage; and
a multiplexer comprising:
a fifth transistor which is connected between the third transistor and the first intermediate node, and is configured to operate according to an offset calibration enable signal;
a sixth transistor which is connected between the fourth transistor and the second intermediate node, and is configured to operate according to the offset calibration enable signal;
a seventh transistor which is connected between the first transistor and the first intermediate node, and is configured to operate according to an inversion signal corresponding to an inverse of the offset calibration enable signal; and
an eighth transistor which is connected between the second transistor and the second intermediate node, and is configured to operate according to the inversion signal.

14. The receiver circuit of claim 13, further comprising:
a first resistor connected between the first intermediate node and a power voltage; and
a second resistor connected between the second intermediate node and the power voltage.

15. The receiver circuit of claim 14, wherein the fifth transistor is further configured to connect the first intermediate node and the second current source based on the offset calibration enable signal,
wherein the sixth transistor is further configured to connect the second intermediate node and the second current source based on the offset calibration enable signal, and
wherein based on the offset calibration enable signal, differential signals based on the common mode voltage are generated at the first and second intermediate nodes.

16. The receiver circuit of claim 15, wherein the seventh transistor is further configured to connect the first intermediate node and the first current source based on the inversion signal,
wherein the eighth transistor is further configured to connect the second intermediate node and the first current source based on the inversion signal, and
wherein based on the inversion signal, differential signals based on the first and second input differential signals are generated at the first and second intermediate nodes.

17. A receiver circuit comprising:
an input stage circuit comprising:
a multiplexer configured to output a first intermediate differential signal to a first intermediate node and a second intermediate differential signal to a second intermediate node different from the first intermediate node;
a first transistor comprising first and second gate lines extending in a first direction on an active region and spaced apart from each other in a second direction intersecting the first direction, wherein the first transistor is electrically connected to the first intermediate node;
a second transistor comprising a third gate line extending in the first direction between the first and second gate lines, and a fourth gate line extending in the first direction on the active region and different from the third gate line, wherein the second transistor is electrically connected to the first intermediate node;
a first dummy transistor comprising a first dummy gate line extending in the first direction between the first and third gate lines; and
a second dummy transistor comprising a second dummy gate line extending in the first direction between the second and third gate lines;
a subsequent stage circuit configured to perform a waveform adjustment operation or amplification operation on the first and second intermediate differential signals, and output first and second output differential signals; and
a sense amplifier configured to sense data based on the first and second output differential signals.

18. The receiver circuit of claim 17, wherein the multiplexer is further configured to connect the first intermediate node and the second transistor based on an offset calibration enable signal having a high logic value.

19. The receiver circuit of claim 18, wherein the multiplexer is further configured to connect a first input node and the first transistor, and interrupt a connection between the first intermediate node and the second transistor, based on the offset calibration enable signal having a low logic value.

20. The receiver circuit of claim 18, wherein a ground voltage is applied to the first and second dummy gate lines based on the first and second intermediate differential signals.

21. (canceled)
